(19) United States
(12) Patent Application Publication
(10) Pub. No.: US 2009/0212853 A1
(43) Pub. Date: Aug. 27, 2009

(54) APPARATUS FOR SUPPLYING POWER IN SEMICONDUCTOR INTEGRATED CIRCUIT AND INPUT IMPEDANCE CONTROL METHOD OF THE SAME

(75) Inventors: Hyung-Soo Kim, Ichon (KR); Yong Ju Kim, Ichon (KR); Sung Woo Han, Ichon (KR); Hee Woong Song, Ichon (KR); Jae Min Jang, Ichon (KR); Ji Wang Lee, Ichon (KR); Chang Kun Park, Ichon (KR); Ic Su Oh, Ichon (KR); Hae Rang Choi, Ichon (KR); Tae Jin Hwang, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 12/347,318

(22) Filed: Dec. 31, 2008

(30) Foreign Application Priority Data
Feb. 25, 2008 (KR) 10-2008-0016744

(51) Int. Cl. G05F 1/10; H01L 27/00

(52) U.S. Cl. 327/539; 257/532; 327/540; 257/E27.001

(57) ABSTRACT

An apparatus for supplying power in a semiconductor integrated circuit includes a plurality of power lines, each supplying external power to an interior of the semiconductor integrated circuit, and at least one decoupling capacitor set connected to the plurality of power lines and having a resistance value configured to be variable according to a bias voltage.

### CROSS-REFERENCES TO RELATED APPLICATION

The present application claims priority under 35 U.S.C. § 119(a) to Korean application number 10-2008-0016744, filed on Feb. 25, 2008, in the Korean Intellectual Property Office, which is incorporated herein by reference in its entirety as if set forth in full.

### BACKGROUND

1. Technical Field

The embodiments described herein relate to a semiconductor integrated circuit, and more particularly, to an apparatus for supplying power in a semiconductor integrated circuit and an input impedance control method of the same.

2. Related Art

In general, a semiconductor integrated circuit is supplied with power, such as an external power VDD and a ground power VSS, from which the semiconductor integrated circuit can generate and one or more internal voltages, such as a reference voltage VREF, a core voltage VCORE, and/or a peripheral voltage VPERI. Accordingly, the semiconductor integrated circuit includes an apparatus for generating such internal voltages and to supply them to various circuit blocks therein.

As the integration degree and operational speeds of conventional semiconductor integrated circuits increase, a potential level of the external power VDD is lowered. As a result, the external power VDD and the ground power VSS are affected by parasitic components inside the semiconductor integrated circuit, thereby reducing the operational stability of such conventional semiconductor integrated circuits. Accordingly, a conventional integrated semiconductor circuit will often include a plurality of decoupling capacitors to minimize the parasitic components.

However, a decoupling capacitor includes resistance components. As a result, inclusion of the decoupling capacitors results in the inclusion of another parasitic component; an equivalent series resistance (ESR) that is caused by connecting the decoupling capacitors to the inside of the circuit.

Previously, a circuit was designed to disregard the ESR or to reduce or minimize the effects associated with the ESR due to the decoupling capacitor. However, if the ESR generated due to the decoupling capacitor is disregarded, a determination cannot be made as to where the resulting noise is occurring. As a result, such a design scheme was abandoned. In addition, when the ESR due to the decoupling capacitor is minimized, it can negatively affect the performance of various components.

### SUMMARY

An apparatus for supplying power in a semiconductor integrated circuit and an input impedance control method of the same capable of controlling a parasitic component of a decoupling capacitor and corresponding input impedance of a semiconductor integrated circuit to a desired level are described herein.

In one aspect, an apparatus for supplying power in a semiconductor integrated circuit includes a plurality of power lines, each supplying external power to an interior of the semiconductor integrated circuit, and at least one decoupling capacitor set connected to the plurality of power lines and having a resistance value configured to be variable according to a bias voltage.

In another aspect, a method for controlling an input impedance using an apparatus for supplying power in a semiconductor integrated circuit includes varying input impedance of the semiconductor integrated circuit by varying resistance values of a plurality of decoupling capacitors in the apparatus for supplying power, wherein the semiconductor integrated circuit includes a plurality of power lines supplied with external power by the plurality of decoupling capacitors connected to the power lines.

In another aspect, a power supply device of a semiconductor integrated circuit includes a plurality of power lines, each supplying external power to an interior of the semiconductor integrated circuit, a reference voltage generator configured to generate a plurality of reference voltages, each having different voltage levels, a multiplexer configured to select one of the plurality of reference voltages in response to a control signal, and to output the selected one of the plurality of reference voltages as a bias voltage, and a plurality of transistors, each connected to the plurality of power lines, and each configured to receive the bias voltage to vary a channel resistance of the transistor, wherein the channel resistance to be larger than a gate resistance of the transistor.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a schematic circuit diagram of an exemplary apparatus for supplying power in a semiconductor integrated circuit according to one embodiment;

FIG. 2 is a schematic circuit diagram of an exemplary decoupling capacitor set capable of being implemented in the apparatus of FIG. 1 according to one embodiment;

FIG. 3 is a schematic circuit diagram and equivalent circuit diagram of the exemplary decoupling capacitor of FIG. 2 according to one embodiment; and

FIG. 4 is a schematic block diagram of an exemplary bias voltage generator capable of being implemented in the apparatus of FIG. 1 according to one embodiment.

### DETAILED DESCRIPTION

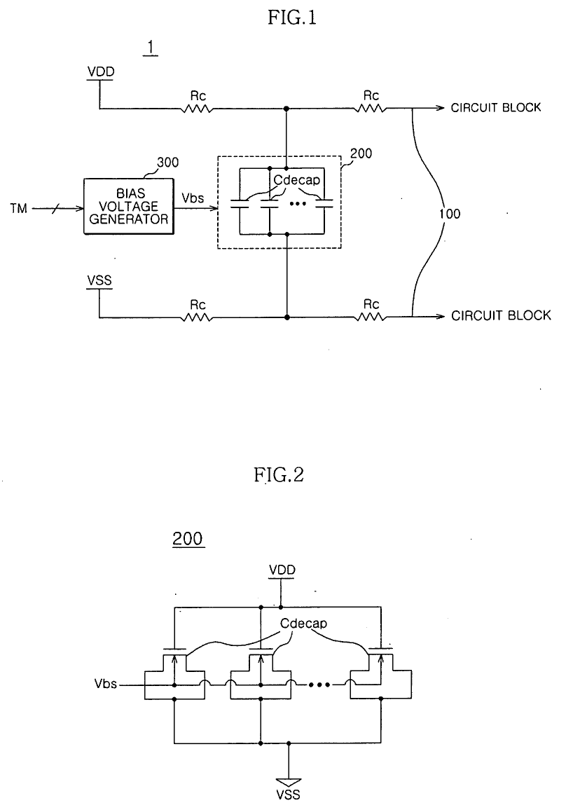

FIG. 1 is a schematic circuit diagram of an exemplary apparatus 1 for supplying power in a semiconductor integrated circuit according to one embodiment. In FIG. 1, the apparatus 1 for supplying power in a semiconductor integrated circuit can include a power line 100, a decoupling capacitor set 200, and a bias voltage generator 300. Here, resistance Rc denotes a resistance component of the power line 100.

The power line 100 can be connected to various circuit blocks inside the semiconductor integrated circuit. Since the power line 100 can supply external power VDD and ground power VSS to the various circuit blocks inside the semiconductor integrated circuit, it can be configured as a mesh.

The decoupling capacitor set 200 can be connected between external power VDD line and the ground power VSS line to minimize parasitic components inside the semiconductor integrated circuit. Although FIG. 1 explicitly shows one decoupling capacitor set 200, but a plurality of decoupling capacitor sets 200 can be connected to the power line 100 as a mesh. Here, the plurality of decoupling sets 200 can be configured to commonly receive the bias voltage Vbs.

The bias voltage generator 300 can be configured to vary and output a level of the bias voltage Vbs in response to a test signal ‘TM’.

FIG. 2 is a schematic circuit diagram of an exemplary decoupling capacitor set 200 capable of being implemented in the apparatus of FIG. 1 according to one embodiment. In FIG. 2, the decoupling capacitor set 200 can include a plurality of decoupling capacitors Cdecap configured of MOS transistors. Here, for example, the plurality of decoupling capacitors Cdecap can be commonly connected to a bulk terminal that can be supplied with the bias voltage Vbs.

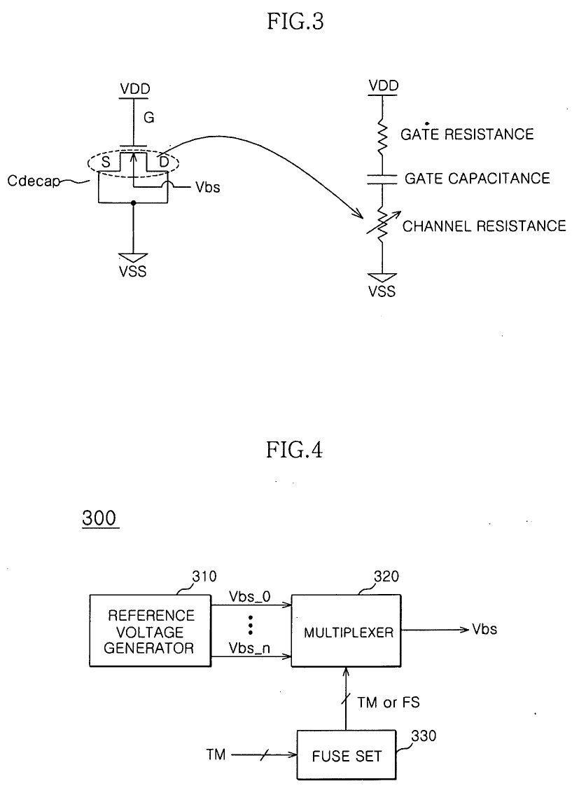

FIG. 3 is a schematic circuit diagram and equivalent circuit diagram of the exemplary decoupling capacitor of FIG. 2 according to one embodiment. At the left side of FIG. 3 is the schematic circuit diagram of the decoupling capacitor, and at the right side of FIG. 3 is an equivalent circuit diagram of the decoupling capacitor.

The decoupling capacitor Cdecap, at the left side of FIG. 3, can be represented by an equivalent circuit, as shown at the right side of FIG. 3. Accordingly, the decoupling capacitor Cdecap shown at the left side of FIG. 3 can be replaced by a gate resistance and a gate capacitance due to the gate terminal and channel resistance being connected to source and drain terminals, respectively.

An equivalent series resistance (ESR) can be determined by the channel resistance and the gate resistance of each of the decoupling capacitors Cdecap, which includes all of the decoupling capacitor sets 200 inside of the semiconductor integrated circuit. Accordingly, the channel resistance of the decoupling capacitor Cdecap can control the ESR. For example, the channel resistance can be larger than the gate resistance when considering the MOS transistor configured as the decoupling capacitor Cdecap. Here, the channel resistance can be effected by the potential level of the bulk terminal such that the channel resistance can be controlled according to the level of the bias voltage Vbs supplied to the bulk terminal. For example, the channel resistance value can be designed to conform to the ESR control range.

One exemplary reason for minimizing the gate resistance is that the fluctuation in the overall resistance value according to the channel resistance control is small when the gate resistance is much larger than the channel resistance.

FIG. 4 is a schematic block diagram of an exemplary bias voltage generator 310 capable of being implemented in the apparatus of FIG. 1 according to one embodiment. In FIG. 4, the bias voltage generator 300 can be configured to include a reference voltage generator 310, a multiplexer 320, and a fuse set 330.

The reference voltage generator 310 can be configured to generate a plurality of reference voltages Vbs_0 to Vbs_n, each having different voltage levels. For example, the reference voltage generator 310 may be configured using a band gap reference circuit.

The multiplexer 320 can be configured to select one of the plurality of reference voltages Vbs_0 to Vbs_n in response to a fuse set signal ‘FS’ or a test signal ‘TM’, and to output the selected one of the plurality of reference voltages Vbs_0 to Vbs_n as the bias voltage Vbs.

The fuse set 330 can be configured to supply the test signal ‘TM’ to the multiplexer 320 during a test mode activation period, and to supply the fuse set signal ‘FS’ generated according to a cutting (conductive) state of the fuse therein during the test mode non-activation period to the multiplexer 320.

The test signal ‘TM’ can be configured of a plurality bits, wherein the test signal ‘TM’ can be selectively activated during the test mode activation period and can be non-activated during the test mode activation period.

An exemplary method for varying an input impedance of a semiconductor integrated circuit using an apparatus for supplying power in the semiconductor integrated circuit will be described with reference to FIG. 4. In a state where the test mode is activated, the test signal ‘TM’ with a specific value can be input.

In FIG. 4, since the test mode is activated, the fuse set 330 can output the test signal ‘TM’ to the multiplexer 320. Then, the multiplexer 320 can select one corresponding test signal ‘TM’ of the reference voltages Vbs_0 to Vbs_n output from the reference voltage generator 310, and can outputs the selected reference voltages Vbs_0 to Vbs_n as the bias voltage Vbs.

The channel resistance of each of the decoupling capacitors Cdecap configuring all of the decoupling capacitor sets 200 inside of the semiconductor integrated circuits according to the bias voltage Vbs output from the multiplexer 320 can be commonly varied. Thus, the equivalent series resistance (ESR) of the overall circuit can be controlled. In addition, the input impedance of the semiconductor integrated circuit can also be changed according to the control of the ESR.

Accordingly, the bias voltage Vbs can be changed and the corresponding input impedance change in the semiconductor integrated circuit can be monitored. For example, the bias voltage Vbs corresponding to the input impedance value capable of showing the optimum performance of the semiconductor integrated circuit can be detected by monitoring the input impedance.

Next, when the detection of the bias voltage Vbs is completed, the cutting (non-conductive transition) on the fuse in the fuse set 330 can be performed to output the same fuse set signal ‘FS’ as the test signal ‘TM’ value. Thus, when the test mode is non-activated, the fuse set 330 can output the fuse set signal ‘FS’ setup in the test mode activation period to the multiplexer 320.

Accordingly, the bias voltage Vbs detected in the test mode activation period can be supplied to all of the decoupling capacitor sets 200 inside of the semiconductor integrated circuit, such that the semiconductor integrated circuit can be operated in a state where the input impedance is set to the optimum value.

While certain embodiments have been described above, it will be understood that the embodiments described are by way of example only. Accordingly, the device and methods described herein should not be limited based on the described embodiments. Rather, the device and methods described herein should only be limited in light of the claims that follow when taken in conjunction with the above description and accompanying drawings.

What is claimed is:

1. An apparatus for supplying power in a semiconductor integrated circuit, comprising:
a plurality of power lines, each supplying external power to an interior of the semiconductor integrated circuit; and
at least one decoupling capacitor set connected to the plurality of power lines and having a resistance value configured to be variable according to a bias voltage.

2. The apparatus for supplying power in a semiconductor integrated circuit according to claim 1, wherein the decoupling capacitor set includes a plurality of transistors, each commonly connected to a bulk terminal.

3. The apparatus for supplying power in a semiconductor integrated circuit according to claim 2, wherein each of the plurality of transistors receives the bias voltage to vary a channel resistance of the transistor.

4. The apparatus for supplying power in a semiconductor integrated circuit according to claim 3, wherein the channel resistance is larger than a gate resistance of each of the plurality of transistors.

5. The apparatus for supplying power in a semiconductor integrated circuit according to claim 2, wherein each of the plurality of transistors is supplied with the bias voltage through the commonly connected bulk terminal.

6. The apparatus for supplying power in a semiconductor integrated circuit according to claim 1, further comprising a bias voltage generator varying a level of the bias voltage in response to a control signal.

7. The apparatus for supplying power in a semiconductor integrated circuit according to claim 6, wherein the bias voltage generator comprises:
a reference voltage generator configured to generate a plurality of reference voltages, each having different voltage levels; and
a multiplexer configured to select one of the plurality of reference voltages in response to the control signal, and to output the selected one of the plurality of reference voltages as the bias voltage.

8. The apparatus for supplying power in a semiconductor integrated circuit according to claim 7, wherein the reference voltage generator includes a band gap reference circuit.

9. The apparatus for supplying power in a semiconductor integrated circuit according to claim 7, wherein the bias voltage generator is configured to receive a test signal as the control signal.

10. The apparatus for supplying power in a semiconductor integrated circuit according to claim 9, wherein the bias voltage generator further comprises a fuse set configured to supply the test signal as the control signal to the multiplexer during a test mode activation period.

11. The apparatus for supplying power in a semiconductor integrated circuit according to claim 10, wherein the fuse set is configured to supply a signal generated according to a conductive state of the fuse therein as the control signal to the multiplexer during the test mode non-activation period.

12. A method for controlling an input impedance using an apparatus for supplying power in a semiconductor integrated circuit, comprising: varying input impedance of the semiconductor integrated circuit by varying resistance values of a plurality of decoupling capacitors in the apparatus for supplying power,
wherein the semiconductor integrated circuit includes a plurality of power lines supplied with external power by the plurality of decoupling capacitors connected to the power lines.

13. The method according to claim 12, wherein the varying resistance values includes changing resistance values of the plurality of decoupling capacitors by varying channel resistance of a plurality of transistors that comprise the plurality of decoupling capacitors.

14. The method according to claim 13, wherein the varying channel resistance includes applying the bias voltage whose level is variable to a bulk terminal of each of the plurality of transistors.

15. A power supply device of a semiconductor integrated circuit, comprising:
a plurality of power lines, each supplying external power to an interior of the semiconductor integrated circuit;
a reference voltage generator configured to generate a plurality of reference voltages, each having different voltage levels;
a multiplexer configured to select one of the plurality of reference voltages in response to a control signal, and to output the selected one of the plurality of reference voltages as a bias voltage; and
a plurality of transistors, each connected to the plurality of power lines, and each configured to receive the bias voltage to vary a channel resistance of the transistor,
wherein the channel resistance to be larger than a gate resistance of the transistor.

16. The power supply device according to claim 15, wherein each of the plurality of transistors is supplied with the bias voltage through a commonly connected bulk terminal.

17. The power supply device according to claim 15, wherein the reference voltage generator includes a band gap reference circuit.

18. The power supply device according to claim 15, wherein the multiplexer receives a test signal as the control signal.

19. The power supply device according to claim 18, further comprising a fuse set configured to supply the test signal to the multiplexer during a test mode activation period.

20. The power supply device according to claim 19, wherein the fuse set is configured to supply a signal generated according to a conductive state of the fuse therein as the control signal to the multiplexer during the test mode non-activation period.
